(19) United States
(12) Patent Application Publication
(10) Pub. No.: US 2024/0404849 A1
(43) Pub. Date: Dec. 5, 2024

(54) SUBSTRATE PROCESSING SYSTEM AND DISPLAY METHOD

(71) Applicant: Tokyo Electron Limited, Tokyo (JP)

(72) Inventors: Tatsuya WATANABE, Yamanashi (JP); Yuichi TAKENAGA, Yamanashi (JP); Shota YAMAZAKI, Tokyo (JP); Youngtai KANG, Tokyo (JP)

(21) Appl. No.: 18/668,806

(22) Filed: May 20, 2024

(30) Foreign Application Priority Data
May 31, 2023 (JP) 2023-090326

(51) Int. Cl. H01L 21/67; H01L 21/673

(52) U.S. Cl. CPC H01L 21/67253; H01L 21/67017; H01L 21/67098; H01L 21/67303

(57) ABSTRACT

A substrate processing system includes a substrate processing apparatus including a processing container and a boat for transferring a plurality of substrates into the processing container; a measuring device that measures a substrate processing result of a substrate in the substrate processing apparatus; and an information processing device that estimates substrate processing results at a plurality of points on the substrate, based on the substrate processing result. The information processing device of the substrate processing system includes an input unit that inputs summary data extracted from the substrate processing result measured by the measuring device, a calculation unit that calculates a plurality of estimated values indicating the substrate processing results at the plurality of points on the substrate based on the summary data; and a display control unit that displays the plurality of estimated values on a display device.

### CROSS-REFERENCE TO RELATED APPLICATIONS

This application is based on and claims priority from Japanese Patent Application No. 2023-090326 filed on May 31, 2023, with the Japan Patent Office, the disclosure of which is incorporated herein in its entirety by reference.

### TECHNICAL FIELD

The present disclosure relates to a substrate processing system and a display method.

### BACKGROUND

Japanese Patent Laid-Open Publication No. 2017-098464 proposes, for example, a heat treatment apparatus for substrates. The heat treatment apparatus includes a calculation unit for calculating a temperature and pressure at which a target heat treatment result is derived, based on a measured heat treatment result, the target heat treatment result, and a heat treatment change model.

### SUMMARY

According to one aspect of the present disclosure, a substrate processing system includes a substrate processing apparatus including a processing container and a boat for transferring a plurality of substrates into the processing container; a measuring device that measures a substrate processing result of a substrate in the substrate processing apparatus; and an information processing device that estimates substrate processing results at a plurality of points on the substrate, based on the substrate processing result. The information processing device of the substrate processing system includes an input unit that inputs summary data extracted from the substrate processing result measured by the measuring device, a calculation unit that calculates a plurality of estimated values indicating the substrate processing results at the plurality of points on the substrate based on the summary data; and a display control unit that displays the plurality of estimated values on a display device.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional schematic view illustrating an example of a substrate processing apparatus according to an embodiment.

FIG. 2 is a configuration diagram illustrating an example of a substrate processing system according to an embodiment.

FIG. 3 is a diagram illustrating an example of a hardware configuration of an information processing device according to an embodiment.

FIG. 4 is a diagram illustrating an example of a functional configuration of the information processing device according to an embodiment.

FIGS. 5A and 5B are diagrams illustrating an example of summary data and film thickness estimated values according to an embodiment.

FIG. 6 is a flow chart illustrating an example of a display method according to an embodiment.

FIG. 7 is a view for explaining summary data according to an embodiment.

FIGS. 8A and 8B are diagrams for explaining a method of calculating film thickness estimated values from summary data based on an approximate model.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the drawings. In the respective drawings, the same components may be denoted by the same reference numerals, and overlapping descriptions thereof may be omitted.

### [Substrate Processing Apparatus]

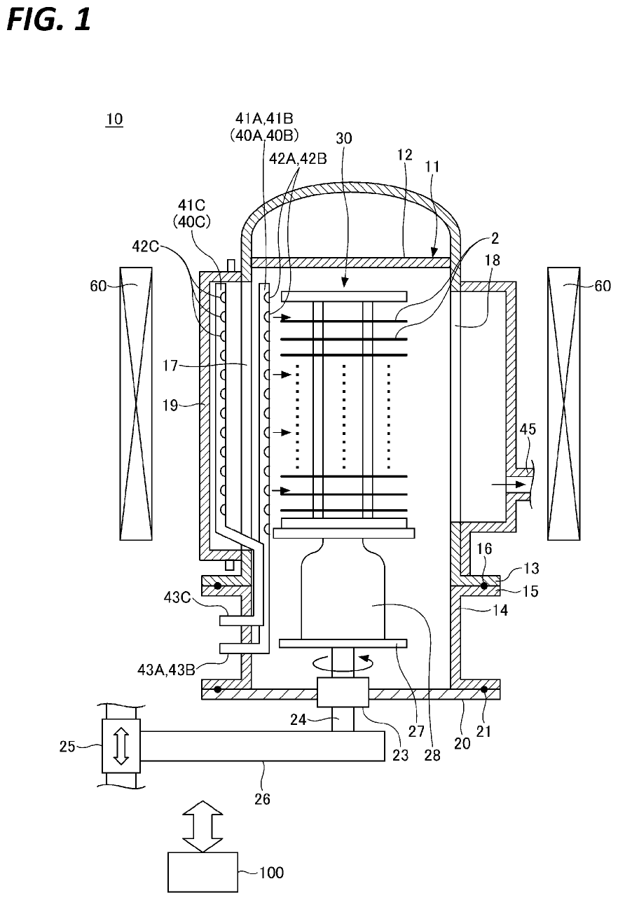

A batch type substrate processing apparatus that performs a desired film forming processing on a plurality of substrates will be described with reference to FIG. 1. FIG. 1 is a cross-sectional schematic view illustrating an example of a substrate processing apparatus 10 according to an embodiment. The substrate processing apparatus 10 accommodates a plurality of wafers 2 in a processing container 11 and forms a film on the plurality of wafers simultaneously.

The substrate processing apparatus 10 is a batch-type vertical heat treatment apparatus that processes the plurality of wafers 2. However, the substrate processing apparatus 10 is not limited to a batch type heat treatment apparatus. For example, the substrate processing apparatus 10 may be a single-wafer processing apparatus that processes wafers one by one. In addition, the substrate processing apparatus 10 may be a semi-batch type apparatus that processes a plurality of substrates at once. The semi-batch type apparatus may be an apparatus that rotates a plurality of wafers disposed around a rotation center line of a rotary table together with the rotary table and sequentially passes them through a plurality of areas to which different kinds of gas are supplied. The substrate processing apparatus 10 is not limited to a film forming apparatus, and may be an apparatus capable of processing a substrate, such as an etching apparatus or a sputtering apparatus.

The substrate processing apparatus 10 includes a processing container 11 that accommodates the wafers 2 and has a space formed therein, where the wafers 2 are processed, a cover member 20 that hermetically blocks an opening in a bottom of the processing container 11, and a boat 30 that holds the wafers 2. The wafer 2 is, for example, a semiconductor substrate (also simply referred to as a substrate), such as a silicon wafer.

The processing container 11 has a cylindrical body 12 of the processing container, which has an open lower end and a ceiling. The body 12 of the processing container is formed, for example, of quartz. A flange portion 13 is formed at the lower end of the body 12 of the processing container. Also, the processing container 11 has a manifold 14, for example, in a cylindrical shape. The manifold 14 is formed, for example, of stainless steel. A flange portion 15 is formed at an upper end of the manifold 14, and the flange portion 13 of the body 12 of the processing container is installed on the flange portion 15. A sealing member 16 such as an O-ring is disposed between the flange portion 15 and the flange portion 13.

The cover member 20 is hermetically attached to the opening at a lower end of the manifold 14 through a sealing member 21 such as an O-ring. The cover member 20 is made of, for example, stainless steel. In a central portion of the cover member 20, a through-hole is formed to penetrate the cover member 20 in a vertical direction. A rotating shaft 24 is disposed in the through-hole. A gap between the cover member 20 and the rotating shaft 24 is sealed by a magnetic fluid sealing portion 23. A lower end of the rotating shaft 24 is rotatably supported by an arm 26 of a lifting and lowering unit 25. A rotating plate 27 is installed on an upper end of the rotating shaft 24. On the rotating plate 27, the boat 30 is installed through a heat insulation stand 28.

The boat 30 holds the plurality of wafers 2 in the vertical direction. For example, in the boat 30 that may hold 200 wafers 2, slots numbered 1 to 200 are disposed in the vertical direction. By disposing the wafers 2 in each of the slots, each of the plurality of wafers 2 are held at horizontal intervals. The boat 30 is formed, for example, of quartz (SiO₂) or silicon carbide (SiC). When the lifting and lowering unit 25 is raised, the cover member 20 and the boat 30 are raised, the boat 30 is carried into an inside of the processing container 11, and the opening at the lower end of the processing container 11 is sealed with the cover member 20. When the lifting and lowering unit 25 is lowered, the cover member 20 and the boat 30 are lowered, and the boat 30 is carried out to the outside of the processing container 11. In addition, when the rotating shaft 24 is rotated, the boat 30 rotates together with the rotating plate 27.

The substrate processing apparatus 10 includes three gas supply pipes 40A, 40B, and 40C. The gas supply pipes 40A, 40B, and 40C are made of, for example, quartz (SiO₂). The gas supply pipes 40A, 40B, and 40C supply gas to the inside of the processing container 11. Types of gas will be described later. A single gas supply pipe may sequentially eject one type or multiple types of gas. Also, a plurality of gas supply pipes may eject the same type of gas.

The gas supply pipes 40A, 40B, and 40C include horizontal pipes 43A, 43B, and 43C that horizontally penetrate the manifold 14, and vertical pipes 41A, 41B, and 41C that are vertically disposed in the inside of the processing container 11. The vertical pipes 41A, 41B, and 41C have a plurality of air supply ports 42A, 42B, and 42C at intervals in the vertical direction. Various types of gas supplied to the horizontal pipes 43A, 43B, and 43C are sent to the vertical pipes 41A, 41B, and 41C and are ejected horizontally from the plurality of air supply ports 42A, 42B, and 42C. The vertical pipe 41C is disposed within a plasma box 19. The vertical pipes 41A and 41B are disposed within the processing container 11.

The substrate processing apparatus 10 includes an exhaust pipe 45. The exhaust pipe 45 is connected to an exhaust device (not illustrated). The exhaust device includes a vacuum pump and evacuates the inside of the processing container 11. An exhaust port 18 is formed in the body 12 of the processing container 11 to evacuate the inside of the processing container 11. The exhaust port 18 is disposed to face the air supply ports 42A, 42B, and 42C. The gas ejected horizontally from the air supply ports 42A, 42B, and 42C passes through the exhaust port 18 and is then exhausted from the exhaust pipe 45. The exhaust device absorbs gas inside the processing container 11 and sends the gas to a removal device. The removal device removes harmful components of the exhaust gas and then releases the exhaust gas into the atmosphere.

The substrate processing apparatus 10 further includes a heating unit 60. The heating unit 60 is disposed in an outside of the processing container 11 and heats the inside of the processing container 11 from the outside of the processing container 11. For example, the heating unit 60 is formed in a cylindrical shape to surround the body 12 of the processing container. The heating unit 60 is formed of, for example, an electric heater. The heating unit 60 heats the inside of the processing container 11, thereby improving processing capability of gas that is supplied into the processing container 11.

An opening 17 is formed in a portion of the body 12 of the processing container in a circumferential direction. The plasma box 19 is formed on a side surface of the processing container 11 to surround the opening 17. The plasma box 19 is formed to protrude outward in a diameter direction from the body 12 of the processing container, and is formed, for example, in a U-shape when viewed in the vertical direction.

A pair of electrodes are disposed to have the plasma box 19 interposed therebetween. The pair of electrodes are a pair of parallel electrodes installed on an outside of the plasma box 19 to face each other. Similar to the vertical pipe 41C, the pair of electrodes are disposed to face each other and formed to be thin and elongated in the vertical direction. The pair of electrodes are connected to an RF power supply through a matcher and are applied with a high-frequency voltage from the RF power supply.

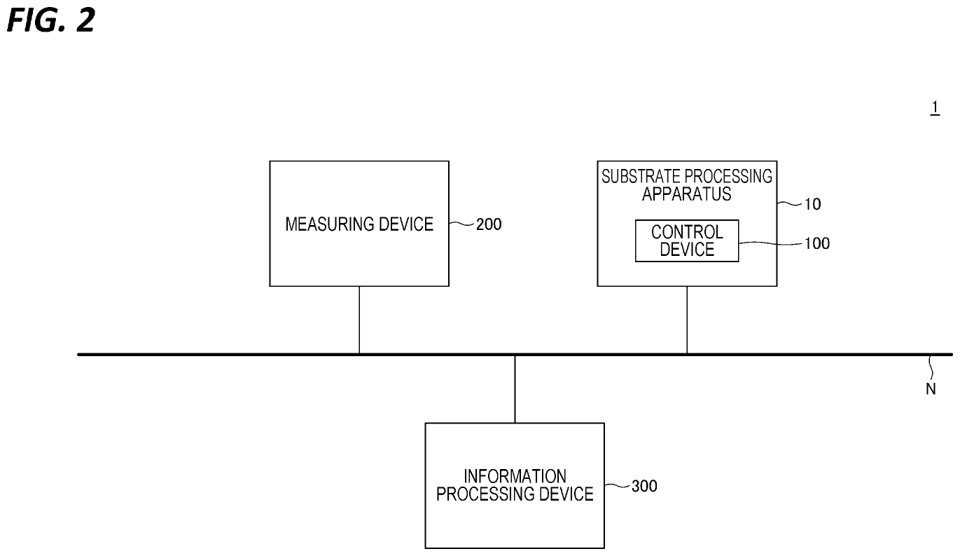

The substrate processing apparatus 10 includes a control device 100. The control device 100 processes computer-executable instructions that cause the substrate processing apparatus 10 to execute various substrate processing processes. The control device 100 may be configured to control each element of the substrate processing apparatus 10 to execute various substrate processing processes. In an embodiment, a part or entirety of the control device 100 may be included in the substrate processing apparatus 10. The control device 100 may include a processing unit, a storage unit, and a communication interface. The control device 100 is implemented by, for example, a computer. The processing unit may be configured to perform various control operations by reading recipes and programs from the storage unit and executing the read recipes and programs. The recipes and programs may be stored in advance in the storage unit, or may be acquired through a medium when necessary. The medium may be various computer-readable storage media, or may be a communication line that is connected to a communication interface. The processing unit may be a central processing unit (CPU). The storage unit may be a random access memory (RAM), a read only memory (ROM), or a hard disk drive (HDD). The communication interface may communicate between the substrate processing apparatus 10, a measuring device 200, and an information processing device 300 (see FIG. 2) through a communication network such as a LAN.

### [Substrate Processing System]

Next, a substrate processing system 1 will be described with reference to FIG. 2. FIG. 2 is a configuration diagram illustrating an example of the substrate processing system 1 according to an embodiment. The substrate processing system 1 includes the substrate processing apparatus 10, the measuring device 200, and the information processing device 300 that are connected to enable data communication through a communication network N such as the Internet or LAN. The control device 100 is inserted into the substrate processing apparatus 10.

As illustrated in FIG. 1, the substrate processing apparatus 10 carries the boat 30 in which the plurality of wafers 2 are placed, into the processing container 11 and performs film forming on the plurality of wafers 2. The measuring device 200 measures a film thickness at a measurement point on a monitor wafer among the wafers 2 on which the film forming is performed in the substrate processing apparatus 10. As for the measuring device 200, for example, an ellipsometer or an optical interferometer (for example, a UV interferometer) may be used.

The film thickness (film thickness measured value) at the measurement point on the monitor wafer, measured by the measuring device 200, is input to the information processing device 300 according to an operator's operation. The number of measurement points on the monitor wafer and the coordinates of the measurement points are set in advance in parameters. The information processing device 300 estimates film thicknesses at a plurality of points on the substrate based on the film thickness measured value. Hereinafter, descriptions will be made on the assumption that a measured value measured by the measuring device 200 is a film thickness, but the measured value indicating a substrate processing result is not limited to the film thickness. The information processing device 300 may estimate substrate processing results at a plurality of points on the substrate based on the substrate processing result.

In the related art, the information processing device 300 determines an in-plane shape of a film thickness formed on the wafer 2 based on a plurality of film thickness measured values at each of a plurality of measurement points and calculates a process condition that fills a gap (difference) between the determined in-plane shape of the film thickness and an in-plane shape of a target film thickness to optimize a recipe.

In this method, in order to calculate optimization of in-plane uniformity of the wafer 2 in the substrate processing apparatus 10, it is necessary to input all of film thicknesses corresponding to measurement points in the wafer 2. For example, when measurement points are 49 measurement points, it is necessary to input film thickness measured values for the 49 measurement points x the number of monitor wafers, resulting in a significant operator load. In addition, in order to ensure calculation accuracy of calculating the optimization of in-plane uniformity, it is desirable to have a larger number of measurement points and monitor wafers.

When film thickness measured values of a film forming result may be transmitted to the information processing device 30, the transmitted film thickness measured values may be copied and pasted into a table illustrating the film forming result. However, when the film forming result may not be transmitted to the information processing device 300, the optimization of the in-plane uniformity of film thicknesses on the wafer 2 may not be calculated. For example, when the film thickness measured values may not be carried out to the outside of a factory where the substrate processing apparatus 10 is disposed due to the reason of information management operation, it is necessary to record all of measurement points and film thickness measured values corresponding thereto and input them to the information processing device 300 manually. In addition, most of the film thickness measured values have decimal places, resulting in a significant operator load. Meanwhile, when the data amount of the film thickness measured values is low, it may be difficult to calculate the optimization of the in-plane uniformity of the film thickness.

Therefore, in the information processing device 300 according to this embodiment, an input of the film thickness measured values for the measurement points x the number of monitor wafers is substituted with an input of summary data extracted from the substrate processing result. Then, film thickness estimated values at a plurality of measurement points are approximated and calculated from the input summary data. Accordingly, the in-plane shape (in-plane distribution) of the film thicknesses on the wafer 2 may be estimated. The calculated plurality of estimated values are displayed on a display device such as a display provided in the control device 100 or the substrate processing apparatus 10. As a result, since the input of film thickness measured values for measurement points x the number of monitor wafers is unnecessary, it is possible to calculate optimization of the in-plane uniformity of the film thicknesses based on a plurality of film thickness estimated values while reducing an operator's operating burden.

In this embodiment, the information processing device 300 determines the in-plane shape of the film thickness formed on the wafer 2 based on the plurality of film thickness measured values at the plurality of measurement points, which are estimated, and calculates a process condition that fills a gap (difference) between the determined in-plane shape of the film thickness and an in-plane shape of a target film thickness to optimize a recipe.

When optimizing a recipe to be used, the information processing device 300 may often input measured values indicating a substrate processing result, such as a film thickness. A recipe optimization device 230 inputs the measured values and optimizes settings of the recipe such as a pressure and temperature to make the substrate processing result indicated by the measured values closer to a target value.

The optimized recipe is transmitted from the information processing device 300 to the control device 100. The control device 100 controls the substrate processing apparatus 10 based on the optimized recipe. Accordingly, the control device 100 may control the substrate processing apparatus 10 so that a target film forming is achieved based on the optimized recipe.

The substrate processing system of FIG. 2 is provided by way of an example, and the information processing device 300 and the control device 100 may be integrated and embedded into the substrate processing apparatus 10 or may be separate from the substrate processing apparatus 10. In addition, the number of each of the substrate processing apparatuses 10, the information processing devices 300, and the measuring devices 200 may be one, but is not limited thereto, and the number of the substrate processing apparatuses 10, the information processing devices 300, and the measuring devices 200 may be two or more. Recipe optimization may be performed by a recipe optimization device that is separate from the information processing device 300.

### [Hardware Configuration]

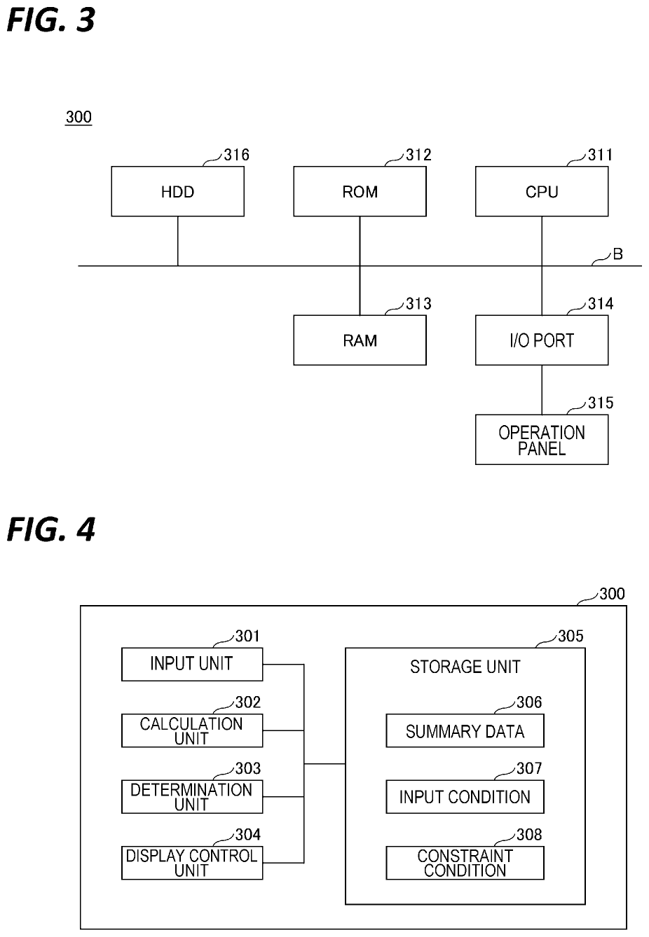

The information processing device 300 is implemented, for example, by a computer with a hardware configuration illustrated in FIG. 3. FIG. 3 is a diagram illustrating an example of a hardware configuration of the information processing device 300 according to an embodiment. The information processing device 300 is configured of, for example, a computer and includes a central processing unit (CPU) 311, a read only memory (ROM) 312, and a random access memory (RAM) 313. In addition, the information processing device 300 includes an I/O port 314, an operation panel 315, and a hard disk drive (HDD) 316. Each part of the information processing device 300 is connected by a bus B.

The CPU 311 is a computing device that implements control or functions of the entire information processing device 300 by reading programs or data from a storage device such as the ROM 312 or the HDD 316 onto the RAM 313 and executing a substrate processing.

The ROM 312 is configured of an electrically erasable programmable ROM (EEPROM), a flash memory, and a hard disk, and is a storage medium that stores programs used by the CPU 311. The RAM 313 functions as a work area of the CPU 311. The programs used by the CPU 311 includes a program for executing a display method to be described later.

The I/O port 314 acquires a measured value such as a film thickness measured by the measuring device 200 and transmits the measured value to the CPU 311. In addition, the operation panel 315 by which a user operates the information processing device 300 is connected to the I/O port 314.

The HDD 316 is an auxiliary storage device and may store programs. The HDD 316 may store log information of data indicating a substrate processing result, such as a film thickness measured by the measuring device 200.

### [Functional Configuration]

Next, a functional configuration of the information processing device 300 will be described with reference to FIG. 4. FIG. 4 illustrates an example of the functional configuration of the information processing device 300 according to an embodiment. The information processing device 300 includes an input unit 301, a calculation unit 302, a determination unit 303, a display control unit 304, and a storage unit 305.

The input unit 301 inputs summary data extracted from a plurality of measured values indicating the substrate processing result. In this embodiment, film thicknesses will be described as an example of the plurality of measured values indicating the substrate processing result. In this case, the measuring device 200 measures film thicknesses as a substrate processing result, and the input unit 301 inputs summary data regarding a film thickness, extracted from the measured film thicknesses. The storage unit 305 stores summary data 306. The summary data 306 is data that numerically indicates a film thickness shape derived from a plurality of film thickness measured values and a characteristic portion of the film thickness shape.

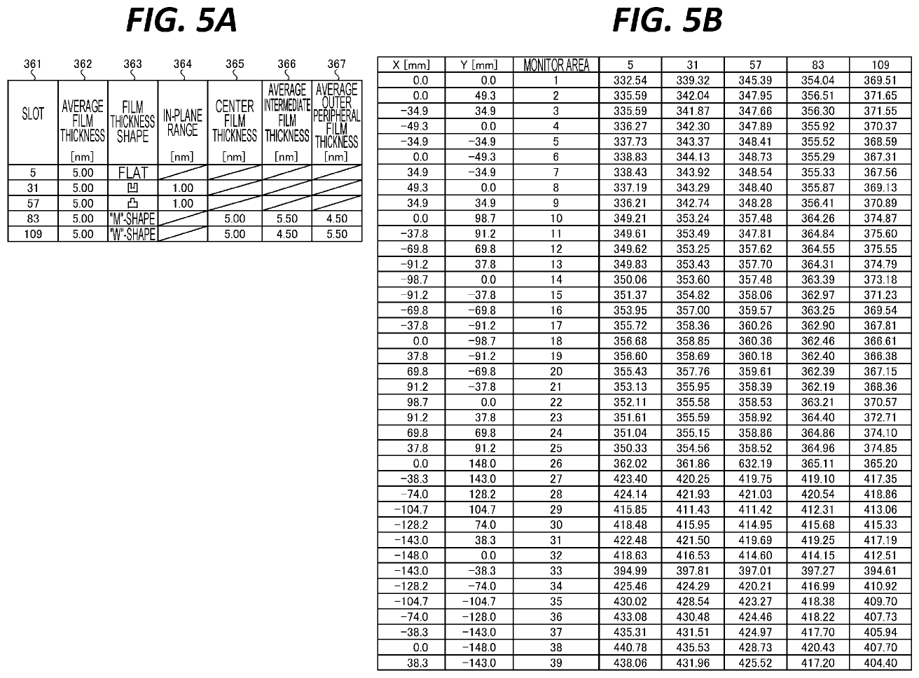

FIG. 5A illustrates an example of the summary data 306 according to an embodiment. In the example of FIG. 5A, the summary data 306 includes a slot number 361, an average film thickness 362, a film thickness shape 363, an in-plane range 364, a center film thickness 365 of a substrate, an average intermediate film thickness 366 of the substrate, and an average outer peripheral film thickness 367 of the substrate.

The slot number 361 is the number of a slot installed in the boat 30. The average film thickness 362 is an average of film thickness measured values measured by the measuring device 200 for a film formed on a monitor wafer placed in each of the slot numbers. The film thickness shape 363 is an in-plane shape (shape of a film surface) of a film thickness on the monitor wafer, which is estimated from the measured film thickness measured values. The film thickness shape 363 may be determined automatically or may be determined by a person with the naked eye. The film thickness shape 363 is one of a flat shape, a concave shape, a convex shape, an “M”-shape (centrally convex), and a “W”-shape (centrally concave). The in-plane range 364 is a difference between a maximum value and a minimum value of the measured film thickness when the in-plane shape is concave or convex.

The center film thickness 365, the average intermediate film thickness 366, and the average outer peripheral film thickness 367 represent a film thickness measured value at a center point, an average of film thickness measured values in an intermediate region, and an average of film thickness measured values in an outer peripheral region, when the substrate is divided into the center point, the intermediate region, and the outer peripheral region surrounding the intermediate region.

In the case of the batch-type substrate processing apparatus 10, a gas flow rate supplied to an upper side of the processing container 11 tends to be lower than that of a lower side of the processing container 11, and in this case, a film thickness shape which is a concave shape or “W”-shape, may be achieved. Meanwhile, the lower side of the processing container 11 tends to have a high gas flow rate, and in this case, a film thickness shape which is a convex shape or “M”-shape may be achieved. Also, since there is temperature fluctuation in the vertical direction of the boat 30, when promoting in-plane uniformity of film thicknesses of the plurality of wafers 2, it is necessary to perform temperature control based on film thickness measured values.

The film thickness measured values measured by the measuring device 200 are input into a table illustrating examples in FIG. 5B, but input errors or omissions may occur during an input operation. In addition, it is necessary to input a film thickness measured value for each of a plurality of slots (slot numbers 5, 31, 57, 83, and 109) at each measurement point (X, Y) in FIG. 5B, thereby resulting in a significant operator load. When an input amount of the film thickness measured values is small, it may be difficult to calculate optimization of in-plane uniformity of the film thickness.

Therefore, in this embodiment, it is unnecessary to input the film thickness measured values to the table illustrating examples in FIG. 5B, and it is only necessary to input the summary data in FIG. 5B. The information processing device 300 automatically calculates and displays (outputs) a film thickness estimated value at each measurement point (X, Y) in FIG. 5B, based on the summary data and an approximate model. This may reduce an operator's effort to input film thicknesses for film thickness adjustment. Further, based on the automatically calculated film thickness estimated values, optimization of the in-plane uniformity of the film thickness may be calculated.

Different pieces of information are input to the summary data 306 depending on a type of the film thickness shape 363. When the film thickness shape 363 is flat, the summary data 306 includes the average film thickness 362 and the film thickness shape 363 for each slot number. When the film thickness shape 363 is concave or convex, the summary data 306 includes the average film thickness 362, the film thickness shape 363, and the in-plane range 364 for each slot number. When the film thickness shape 363 is an “M”-shape or “W”-shape, the summary data 306 includes the average film thickness 362, the film thickness shape 363, the center film thickness 365, the average intermediate film thickness 366, and the average outer peripheral film thickness 367 for each slot number.

In this manner, the summary data 306 includes the average film thickness 362 and the film thickness shape 363. Further, when the film thickness shape 363 is concave or convex, the summary data 306 further includes the in-plane range 364, and when the film thickness shape 363 is an “M”-shape or “W”-shape, the summary data 306 further includes the center film thickness 365, the average intermediate film thickness 366, and the average outer peripheral film thickness 367.

Based on the summary data 306, the calculation unit 302 calculates a plurality of estimated values indicating substrate processing results at a plurality of points. For example, the calculation unit 302 approximates and calculates film thickness estimated values at a plurality of points (e.g., a plurality of measurement points) as information on in-plane distribution of the film thickness. The film thickness estimated values are an example of the plurality of estimated values indicating the substrate processing results.

The determination unit 303 determines whether the summary data 306 satisfies an input condition 307 by referring to the storage unit 305. The input condition 307 is stored in advance in the storage unit 305.

When it is determined that the summary data 306 satisfies the input condition 307, the calculation unit 302 calculates a plurality of estimated values from the summary data 306.

When it is determined that the summary data 306 does not satisfy the input condition 307, the display control unit 304 indicates (notifies) that the summary data 306 does not satisfy the input condition 307. When an input value with, for example, an incorrect number of digits is input as the summary data 306, the determination unit 303 determines that the summary data 306 does not satisfy the input condition 307, and the display control unit 304 indicates that the input number of digits of the film thickness is incorrect.

To optimize the recipe, the input unit 301 inputs, for example, a target film thickness shape (an in-plane shape of the film thickness). The calculation unit 302 calculates a process condition that fills a gap (difference) between a film thickness shape (in-plane shape of the film thickness) calculated from a plurality of film thickness estimated values and the target film thickness shape.

The determination unit 303 determines whether the calculated process condition satisfies a constraint condition 308. The constraint condition 308 is stored in advance in the storage unit 305. When it is determined that the process condition does not satisfy the constraint condition 308, the display control unit 304 determines that the process condition violates the constraint condition 308 of the apparatus and indicates (notifies) that a sufficient improvement effect may not be obtained since the process condition exceeds the constraint condition. Meanwhile, when it is determined that the process condition satisfies the constraint condition 308, a recipe is optimized according to the process condition, and based on the optimized recipe, the next film forming process is performed in the substrate processing apparatus 10.

The input unit 301 is implemented by, for example, the operation panel 315 and the I/O port 314. The calculation unit 302, the determination unit 303, and the display control unit 304 are implemented by the CPU 311, for example. The storage unit 305 is implemented by, for example, the ROM 312, the RAM 313, and the HDD 316.

### [Compensation Method]

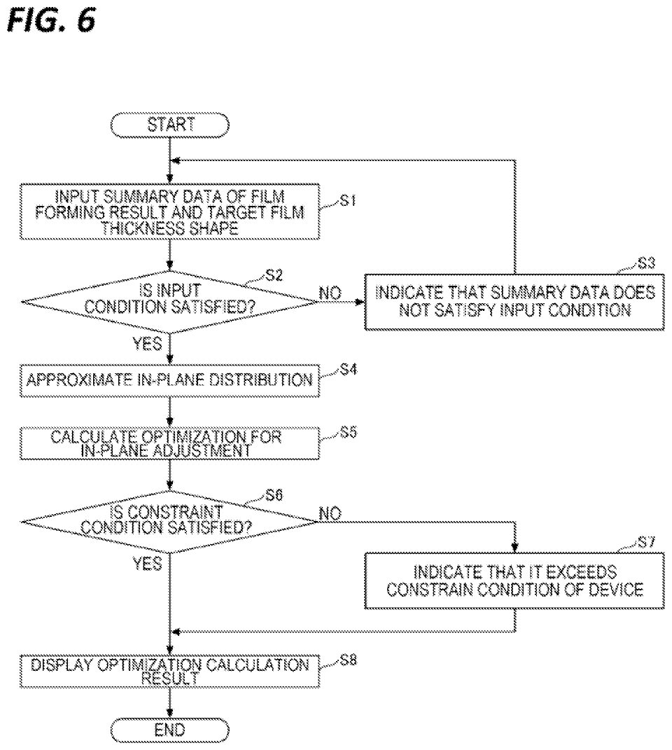

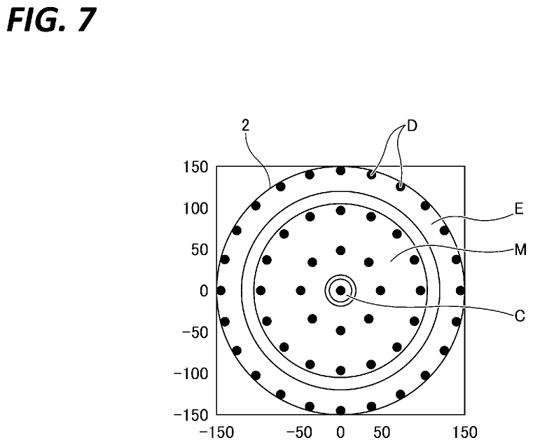

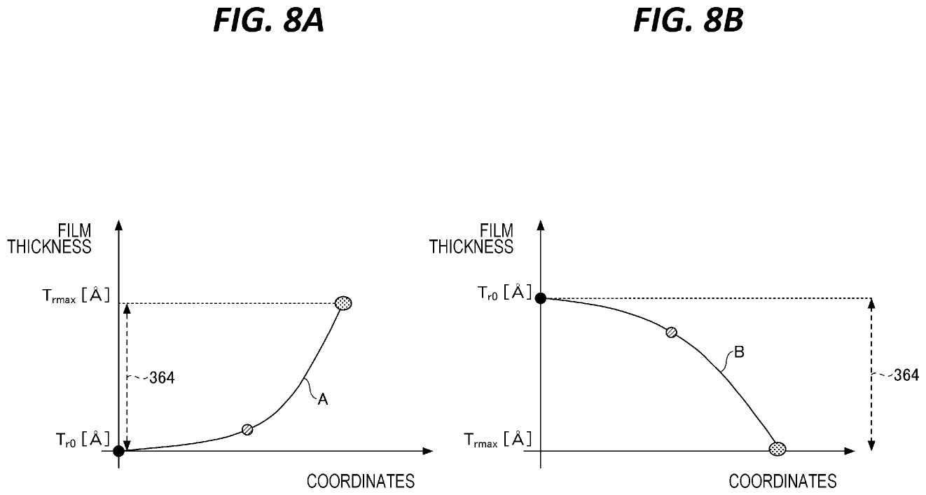

An example of a display method according to an embodiment will be described with reference to FIGS. 6, 7, 8A and 8B. FIG. 6 is a flow chart illustrating an example of a display method according to an embodiment. FIG. 7 is a view for explaining summary data according to an embodiment. FIGS. 8A and 8B are diagrams for explaining a method of calculating film thickness estimated values from the summary data based on an approximate model.

The display method according to this embodiment is executed by the information processing device 300. At least one monitor wafer is prepared for each lot in which 25 wafers to be processed by the substrate processing apparatus 10 are stored, and then, measurement of a film thickness by the measuring device 200 is performed on the monitor wafer.

When a processing of the display method in FIG. 6 begins, the input unit 301 inputs summary data extracted from film thickness measured values which are a film forming result, and a target film thickness shape, in step S1. The summary data and the target film thickness shape are stored in the storage unit 305. Next, in step S2, the determination unit 303 determines whether the input summary data satisfies the input condition by referring to the input condition stored in the storage unit 305. As for the input condition, a normal film thickness range that may be taken as the average film thickness 362, for example, is set.

In step S2, when the determination unit 303 determines that the input summary data does not satisfy the input condition, the display control unit 304 indicates (notifies) that the summary data does not satisfy the input condition in step S3. For example, when the input number of digits of the summary data, such as a film thickness, is incorrect, the display control unit 304 indicates the error of the input number of digits of the film thickness. Then, returning to step S1, the input unit 301 inputs new summary data and proceeds to the processing of step S2.

In step S2, when the determination unit 303 determines that the input summary data satisfies the input condition, the processing proceeds to step S4, and the calculation unit 302 approximates the in-plane distribution of the film thickness based on the summary data. Accordingly, the calculation unit 302 calculates a plurality of film thickness estimated values indicating film forming results at a plurality of points.

For example, when the film thickness shape 363 of the summary data illustrated in slot number 5 in FIG. 5A is flat, the calculation unit 302 substitutes the average film thickness into the plurality of film thickness estimated values at the plurality of points.

For example, when the film thickness shape 363 of the summary data illustrated in slot numbers 31 and 57 in FIG. 5A is concave or convex, the calculation unit 302 calculates a film thickness T at a distance r from the center of the wafer 2 using the approximate equation T=ar²+b (Equation A). Here, a represents a film thickness shape and b represents a film thickness at the center of the wafer 2.

When the film thickness shape 363 is concave, if the approximate equation (Equation A) for a film thickness of an outermost periphery (outermost periphery film thickness) is modified, as illustrated in curve A in FIG. 8A, the outermost periphery film thickness indicates a maximum value Tᵣₘₐₓ of the film thickness, and a center film thickness indicates a minimum value Tᵣ₀ of the film thickness. Therefore, the in-plane range 364 is a value obtained by subtracting the center film thickness from the outermost periphery film thickness and is expressed by the following equation.

$${T}_{rmax} - {T}_{rO} = {ar}_{max}^{2} + {T}_{rO} - {T}_{rO}$$

From the above, Equation 1 is derived.

$$a = \frac{{T}_{{r}_{max}} - {T}_{{r}_{0}}}{{r}_{max}^{2}} = \frac{range}{{r}_{max}^{2}} \qquad [ Equation 1 ]$$

When the film thickness shape 363 is convex, if the approximate equation (Equation A) for the outermost periphery film thickness is modified, as illustrated in curve B in FIG. 8B, the center film thickness indicates a maximum value Tᵣ₀ of the film thickness, and the outermost periphery film thickness indicates a minimum value Tᵣₘₐₓ of the film thickness. Therefore, the in-plane range 364 is a value obtained by subtracting the outermost periphery film thickness from the center film thickness and is expressed by the following equation.

$${T}_{rmax} - {T}_{rmax} = {ar}_{max}^{2} + {T}_{rO} - {T}_{rmax}$$

From the above, Equation 2 is derived.

$$a = - \frac{{T}_{{r}_{0}} - {T}_{{r}_{max}}}{{r}_{max}^{2}} = - \frac{range}{{r}_{max}^{2}} \qquad [ Equation 2 ]$$

From Equation 1 and Equation 2, a is calculated. a is a value indicating a film thickness shape. Next, b is calculated. b is a center film thickness. An average film thickness Tₐᵥₑ of one wafer is calculated by Equation 3.

$${T}_{ave} = \frac{{T}_{{r}_{0}} * {pointNum}_{{r}_{0}} + … + {T}_{{r}_{max}} * {pointNum}_{{r}_{max}}}{{pointNum}_{total}} \qquad [ Equation 3 ]$$

“pointNum” in Equation 3 indicates the number of measurement points with the same distance from the center. For example, approximation is made using measurement points illustrated in FIG. 7. Equation 4 is substituted for each measurement point.

$$T = {ar}^{2} + b = \pm \frac{range}{{r}_{max}^{2}} {r}^{2} + {T}_{{r}_{0}} \qquad [ Equation 4 ]$$

The input average film thickness Tₐᵥₑ is also substituted to calculate the center film thickness Tᵣ₀. Accordingly, a (film thickness shape) and b (center film thickness) of the approximate equation (Equation A) T=ar²+b are determined.

Therefore, when the film thickness shape 363 is concave, the calculation unit 302 substitutes the film thickness shape a obtained based on Equation 1 and the center film thickness b into the approximate equation (Equation A) and calculates a plurality of film thickness estimated values T at a plurality of points (X, Y) from the distance r from the center of the wafer, using the approximate equation.

In addition, when the film thickness shape 363 is convex, the calculation unit 302 substitutes the film thickness shape a obtained based on Equation 2 and the center film thickness b into the approximate equation (Equation A), and calculates a plurality of film thickness estimated values T at a plurality of points (X, Y) from the distance r from the center of the wafer, using the approximate equation.

When the film thickness shape 363 is an “M”-shape or “W”-shape, the calculation unit 302 substitutes the center film thickness 365, the average intermediate film thickness 366, and the average outer peripheral film thickness 367 into the film thickness estimated values. For example, as illustrated in FIG. 7, it is assumed that measurement points D are set in each of a center C, an intermediate region M, and an outer peripheral region E of the wafer 2. The calculation unit 302 substitutes the center film thickness 365 into a film thickness estimated value at a measurement point in the center C of the wafer 2. In addition, the calculation unit 302 substitutes the average intermediate film thickness 366 into a film thickness estimated value at a measurement point in the intermediate region M of the wafer 2. Further, the calculation unit 302 substitutes the average outer peripheral film thickness 367 into a film thickness estimated value at a measurement point in the outer peripheral region E of the wafer 2. For example, from the summary data of slot number 83 in FIG. 5A, 5.00 is substituted into the film thickness estimated value at the measurement point in the center C. In addition, 5.50 is substituted into the film thickness estimated value at the measurement point in the intermediate region M. Additionally, 4.50 is substituted into the film thickness estimated value at the measurement point in the outer peripheral region E.

Referring back to FIG. 6, next, in step S5, the calculation unit 302 calculates optimization for in-plane adjustment. Specifically, the calculation unit 302 determines in-plane film thickness distribution of the wafer 2 based on a plurality of film thickness measured values at a plurality of measurement points, which are estimated, and calculates a process condition that fills a gap between a determined in-plane shape of the film thickness and an in-plane shape of a target film thickness to calculate optimization of a recipe.

Next, in step S6, the determination unit 303 determines whether a process condition of an optimization calculation result satisfies the constraint condition 308. When the determination unit 303 determines that the process condition satisfies the constraint condition 308, the display control unit 304 displays the process condition of the optimization calculation result on a display device in step S8 and terminates the processing. The display device may be a display of the control device 100 or the substrate processing apparatus 10.

When the determination unit 303 determines that the process condition does not satisfy the constraint condition 308 in step S6, the display control unit 304 indicates (notifies) that the process condition exceeds the constraint condition of the substrate processing apparatus 10 in step S7. For example, a process condition that sets a temperature range beyond performance of the substrate processing apparatus 10 violates the constraint condition. In this manner, when a constraint condition of the temperature range that may be changed for optimization or a constraint condition of a heater power (temperature control) installed in the substrate processing apparatus 10 is not satisfied, the display control unit 304 notifies that the process condition exceeds the constraint condition and a sufficient improvement effect may not be obtained. Then, the display control unit 304 displays the process condition of the optimization calculation result on the display device in step S8, and terminates the processing.

As described above, according to the display method and the information processing device 300 in this embodiment, it is possible to reduce a user's load of inputting film thickness measured values for in-plane adjustment of films. That is, the input of film thickness measured values for measurement points x the number of monitor wafers is substituted with the input of summary data extracted from the substrate processing results. Then, the film thickness estimated values at a plurality of measurement points are approximated and calculated from the input summary data. Accordingly, a film thickness shape (in-plane distribution of a film thickness) on the wafer 2 may be estimated. The plurality of calculated film thickness estimated values are provided, for example, in a table format as illustrated in FIG. 5B and displayed on the display of the control device 100 or the substrate processing apparatus 10. As a result, it is not necessary to input film thickness measured values for measurement points x the number of monitor wafers, thereby reducing an operator's operation burden. For example, even when film thickness measured values may not be carried out of a factory where the substrate processing apparatus 10 is installed due to the reason of information management operation, it is possible to calculate optimization of in-plane uniformity of a film thickness while reducing an operator load by the display method according to this embodiment.

According to one aspect of the present disclosure, in-plane distribution on a substrate may be estimated from summary data of a substrate processing result.

From the foregoing content, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing system comprising:
a substrate processing apparatus including a processing container and a boat for transferring a plurality of substrates into the processing container;
a measuring sensor configured to measure a substrate processing result of a substrate in the substrate processing apparatus; and
an information processing device configured to estimate substrate processing results at a plurality of points on the substrate, based on the substrate processing result,
wherein the information processing device includes,
an input circuitry configured to input summary data extracted from the substrate processing result measured by the measuring sensor,
a calculation circuitry configured to calculate a plurality of estimated values indicating the substrate processing results at the plurality of points on the substrate based on the summary data; and
a display control circuitry configured to display the plurality of estimated values on a display device.

2. The substrate processing system according to claim 1, wherein the measuring sensor measures a film thickness as the substrate processing result,
the input circuitry inputs summary data regarding a film thickness, extracted from the measured film thickness, and
the calculation circuitry calculates the plurality of estimated values of the film thickness at the plurality of points on the substrate from the summary data.

3. The substrate processing system according to claim 2, wherein the summary data includes at least an average film thickness and a film thickness shape on the substrate.

4. The substrate processing system according to claim 3, wherein the summary data includes a difference between a maximum value and a minimum value of the measured film thickness when the film thickness shape is concave or convex.

5. The substrate processing system according to claim 3, wherein, when the film thickness shape is an “M”-shape or “W”-shape, the summary data includes a film thickness at a center of the substrate, an average film thickness at an intermediate portion of the substrate, and an average film thickness at an outer periphery of the substrate among the measured film thicknesses.

6. The substrate processing system according to claim 1, further comprising:
a storage configured to store an input condition; and
a determination circuitry configured to determine whether the summary data satisfies the input condition by referring to the storage,
wherein, when determined that the summary data satisfies the input condition, the calculation circuitry calculates the plurality of estimated values from the summary data.

7. The substrate processing system according to claim 6, wherein when determined that the summary data does not satisfy the input condition, the display control circuitry displays that the summary data does not satisfy the input condition.

8. The substrate processing system according to claim 1, wherein the input circuitry inputs a target film thickness shape,
the calculation circuitry calculates a process condition that fills a gap between a film thickness shape calculated from the plurality of estimated values and the target film thickness shape,
wherein the information processing device further includes,
a storage configured to store a constraint condition, and
a determination circuitry configured to determine whether the process condition satisfies the constraint condition by referring to the storage, and
wherein when determined that the process condition satisfies the constraint condition, the display control circuitry displays the process condition on the display device.

9. The substrate processing system according to claim 8, wherein when determined that the process condition does not satisfy the constraint condition, the display control circuitry displays that the process condition exceeds the constraint condition.

10. A display method of a substrate processing system, the display method comprising:
inputting summary data extracted from a substrate processing result of a substrate measured by a measuring sensor in a substrate processing apparatus of the substrate processing system, the substrate processing apparatus including a processing container and a boat that transfers a plurality of substrates into the processing container;
calculating a plurality of estimated values indicating substrate processing results at a plurality of points on the substrate based on the summary data inputted at the inputting; and
displaying the plurality of estimated values on a display device.
